(19) United States
(12) Patent Application Publication
(10) Pub. No.: US 2026/0090291 A1
(43) Pub. Date: Mar. 26, 2026

(54) TWO-TERMINAL MIXED-IONIC-ELECTRONIC-CONDUCTION RANDOM ACCESS MEMORY (MIECRAM) DEVICE

(71) Applicant: International Business Machines Corporation, Armonk, NY (US)

(72) Inventors: Kevin Wayne Brew, Niskayuna, NY (US); Ching-Tzu Chen, Ossining, NY (US); JIN PING HAN, Yorktown Heights, NY (US); Timothy Mathew Philip, Albany, NY (US)

(21) Appl. No.: 18/892,326

(22) Filed: Sep. 20, 2024

(51) Int. Cl. H10N 70/00; G11C 13/00; H10B 63/00; H10N 70/20

(52) U.S. Cl. CPC H10N 70/8833; G11C 13/0026; G11C 13/0028; G11C 13/0038; G11C 13/004; G11C 13/0069; H10B 63/30; H10N 70/021; H10N 70/063; H10N 70/066; H10N 70/253

(57) ABSTRACT

A memory device includes a bottom electrically conductive layer, with a mobile ionizable species, and having an electrical resistance that is less than 5 percent of the overall resistance of the memory device. A barrier layer is outward of the bottom electrically conductive layer and has a higher ion chemical potential relative to the electrically conductive layer. A mixed-ionic-electronic-conduction (MIEC) switching layer is outward of the barrier layer and has an electrical conductivity dependent on ion concentration within the MIEC layer. A top contact is outward of the mixed-ionic-electronic-conduction (MIEC) switching layer.

### BACKGROUND

The present invention relates generally to the electrical, electronic and computer arts and, more particularly, to memristive devices suitable for analog in-memory computing.

Electronic-Conduction Random Access Memory (ECRAM) devices are one of the few memristive devices that can be easily engineered to achieve symmetric switching needed for ideal analog in-memory computing operations. Though improvements to algorithms (e.g., Tiki-Taka) and hardware-aware training can be used to implement non-symmetric memristive devices, this makes implementation of analog devices more difficult. ECRAM devices have historically used Li+ or mobile-ion for programming, which causes difficulty with CMOS (complementary metal oxide semiconductor) compatibility.

### BRIEF SUMMARY

Principles of the invention provide techniques for a two-terminal MIECRAM device. In one aspect, an exemplary memory device includes a bottom electrically conductive layer, with a mobile ionizable species, and having an electrical resistance that is less than 5 percent of the overall resistance of the memory device; a barrier layer, outward of the bottom electrically conductive layer and having a higher ion chemical potential relative to the bottom electrically conductive layer; a mixed-ionic-electronic-conduction (MIEC) switching layer, outward of the barrier layer and having an electrical conductivity dependent on ion concentration within the MIEC layer; and a top contact outward of the mixed-ionic-electronic-conduction (MIEC) switching layer.

In another aspect, an exemplary memory array includes a plurality of word lines; a plurality of bit lines intersecting the plurality of word lines at a plurality of cell locations, each bit line being paired with a corresponding complementary bit line; and a plurality of cells respectively located at the plurality of cell locations. Each cell of the plurality of cells in turn comprises: a memory device and an access transistor. The memory device in turn includes: a bottom electrically conductive layer, with a mobile ionizable species, and having an electrical resistance that is less than 5 percent of the overall resistance of the memory device; a barrier layer, outward of the bottom electrically conductive layer and having a higher ion chemical potential relative to the bottom electrically conductive layer; a mixed-ionic-electronic-conduction (MIEC) switching layer, outward of the barrier layer and having an electrical conductivity dependent on ion concentration within the MIEC layer; and a top contact outward of the mixed-ionic-electronic-conduction (MIEC) switching layer, connected to a corresponding bit line. The access transistor has a gate connected to a corresponding one of the plurality of word lines, a drain connected to the bottom electrically conductive layer, and a source connected to the corresponding complementary bit line.

In still another aspect, an exemplary method of manufacturing an array of memory devices, includes forming a metal hydride layer; forming a barrier layer outward of the metal hydride layer; forming a mixed-ionic-electronic-conduction (MIEC) switching layer outward of the barrier layer to form a first intermediate structure; etching the first intermediate structure to form a plurality of devices; filling first dielectric material between the plurality of devices and planarizing to form a second intermediate structure; depositing a top contact metal layer over the second intermediate structure; etching the top contact metal layer to form a plurality of bit lines; and filling second dielectric material between the plurality of bit lines, and planarizing.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor and/or by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
a CMOS-compatible MIECRAM device that removes non-CMOS compatible electrolytes, such as a sulfonated tetrafluoroethylene based fluoropolymer-copolymer such as NAFION® (registered mark of THE CHEMOURS COMPANY FC, LLC, Wilmington, DELAWARE, USA);
a CMOS-compatible MIECRAM device that achieves low-power, nonvolatile, bipolar, and near symmetric switching, with decoupled Read and Write threshold voltages.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-3 show a mixed ionic electronic electrochemical cell during write and read operations, in accordance with aspects of the invention;

FIGS. 4-10 show steps in forming an array of such cells, according to an aspect of the invention; and

FIGS. 11 and 12 show an array of such cells, according to an aspect of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As noted, ECRAM devices are one of the few memristive devices that can be easily engineered to achieve symmetric switching needed for ideal analog in-memory operation. Though improvements to algorithms (Tiki-Taka) and hardware-aware training can be used to implement non-symmetric memristive devices, this makes implementation of analog devices harder. ECRAM devices have historically used Li+ or mobile-ion for programming; however, H+ is more CMOS compatible.

A known three-terminal ECRAM using H+ for programming uses NAFION® material, which is not CMOS compatible. Furthermore, integration of three terminal devices is more difficult than two terminal devices. In the past, a two terminal symmetric stack MIECRAM device has required one thickness of the MIEC layers to be thicker than the other in order to induce a net resistance change by breaking the layer symmetry, since both layers change resistance during programming. In addition, devices based on Li+ are slow—such devices can only achieve approximately microsecond operation by dimensional scaling less than 50 nm.

One or more embodiments employ a charge-transfer ion barrier layer, such as graphene or graphene oxide, to allow for two terminal read/write of the device. One or more embodiments utilize only a single layer of Mixed-Ionic-Electronic-Conduction (MIEC) material with a high resistance to control the resistance of the memristor. One or more embodiments employ appropriate electrically conductive metal hydride with a similar chemical potential for the ion (H+) to achieve near-symmetric switching.

One or more embodiments accordingly provide a Mixed-Ionic-Electronic-Conduction random-access memory (MIECRAM)—which is an analog device that changes resistance based on moving ions and can be used, for example, as a synaptic device for artificial intelligence (AI) applications. A three-terminal prior art device has been shown to work and has exhibited some symmetry switching. The prior art provides a channel of tungsten trioxide and a solid electrolyte that blocks current but allows ions to pass. In the palladium hydride gate terminal, hydrogen is solubilized within the metal palladium to serve as a proton reservoir, and proton transfer occurs across the electrolyte upon applying a gate voltage. Once a proton enters the tungsten trioxide channel and intercalates with tungsten trioxide, it increases the conductivity of the channel. The prior-art three-terminal device essentially shuttles protons back and forth, as the protonation/deprotonation process is reversible. However, it disadvantageously has a large footprint.

One or more embodiments advantageously provide a vertical channel in two-terminal device. It should be noted that, with just palladium and tungsten trioxide, hydrogen will react with the tungsten trioxide and some equilibrium will be reached. If such a device was pulsed, it would first move away from equilibrium but would relax back. One or more embodiments advantageously overcome these limitations by inserting an ultrathin ion barrier with high electrical conductivity, such as graphene. Upon potentiation, protons can be transported through graphene between the palladium hydride reservoir and the tungsten oxide channel. Other ultrathin monolayer or few-atomic-layer electrically conductive materials with a thickness <˜5 nm can also be used. One or more embodiments employ a material with a high proton chemical potential that acts like a potential energy barrier for the proton to cross.

When applying a small bias voltage (<˜0.5V), the ion barrier layer prevents proton transfer across the barrier, thereby allowing for READ of the device resistance with minimal disturbance to the channel. When applying a high enough bias voltage (˜0.5-2V), there is sufficient energy to cross the potential energy barrier for proton transfer between the metal hydride reservoir and the channel, thereby varying the hydrogen concentration in the channel to WRITE the device resistance. Since the proton-transfer process is bidirectional and the chemical potential in the metal hydride reservoir is comparable to that in the channel, this 2-terminal device can enable near-symmetric WRITE.

Referring to FIGS. 1-3, one or more embodiments provide a mixed ionic electronic electrochemical cell including a bottom ion adsorbed metal 301, an anodic (relative to transporting ion) ultrathin ion (charge-transfer) barrier layer 303 with high ion conductivity and electrical conductivity, an MIEC switching layer 305 whose conductivity is dependent on the ion concentration within the layer, and a top contact metal 307. In one or more embodiments, the chemical potential of the ion in the MIEC switching layer is approximately the same as that of the absorbed ion in the metal hydride layer 301.

In a non-limiting example of forming the bottom ion adsorbed metal 301, one or more embodiments include deposition of blanket Pd with plasma/H2 gas treatment to create a metal hydride. This is followed by two-dimensional barrier deposition to create ion potential energy barrier 303 (e.g., graphene/graphene oxide). In a non-limiting example, the MIEC switching layer 305 is a protonic switching memristive mixed ionic electronic conducting (MIEC) material (e.g. WO_{3-y}). The top metal contact 307 can be formed, for example, from Pd or an alternative metal. The similar metal in the top and bottom metal contacts helps ensure similar bipolar switching by matching the same work function of the electrodes. Further exemplary fabrication details are provided elsewhere herein in connection with FIGS. 4-10.

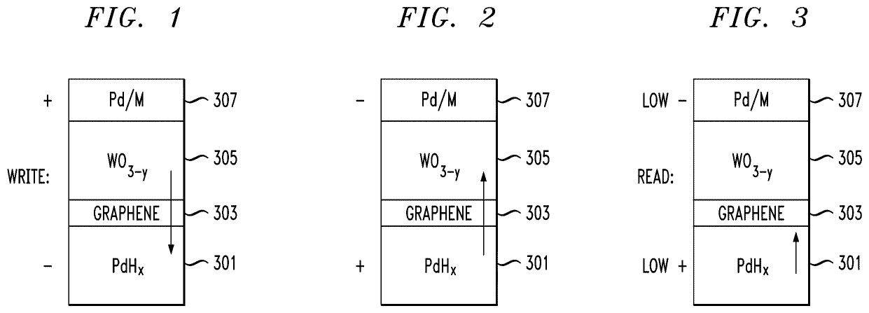

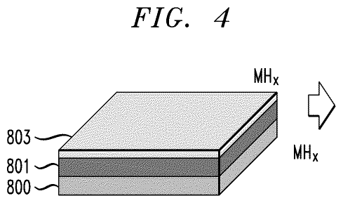

At low bias (less than about 0.5V)(see discussion of FIG. 3 elsewhere herein), the field is not high enough to initiate the charge transfer reaction of chemisorbed hydrogen into the graphene and across. The graphene is anodic with respect to ions such as H+ and Li+. Graphene oxide transports protons rapidly. This operation is a read of the WO_{3-y} layer which is dependent on hydrogen concentration. At high bias (about 0.5-2V), depending on the polarity of the field, the H+ can be moved into and out of the WO_{3-y} layer, writing the resistance of the device (see discussion of FIG. 1 elsewhere herein for WRITE and FIG. 2 for READ).

Referring to FIGS. 1-3, in one or more embodiments, the only material that is changing its resistance is WO_{3-y}; it has a similar chemical potential for the protons and the palladium hydride. FIG. 1 shows the top electrode positive and the bottom electrode negative. FIG. 2 shows the top electrode negative and the bottom electrode positive. In FIG. 2, the hydrides migrate upward, and the WO_{3-y} is deoxidized and becomes more conductive. However, if the top electrode is negative and the bottom electrode is positive but the voltage is too low as in FIG. 3, the hydrides move upward but cannot cross over the graphene.

Thus, one or more embodiments employ a charge-transfer ion barrier layer, such as graphene or graphene oxide, to allow for two-terminal read/write of a device. Below a relatively low voltage threshold, it is possible to read the device as it yields a certain resistance versus voltage. Above that threshold, the resistance changes (increases or decreases, such that a READ would be destructive).

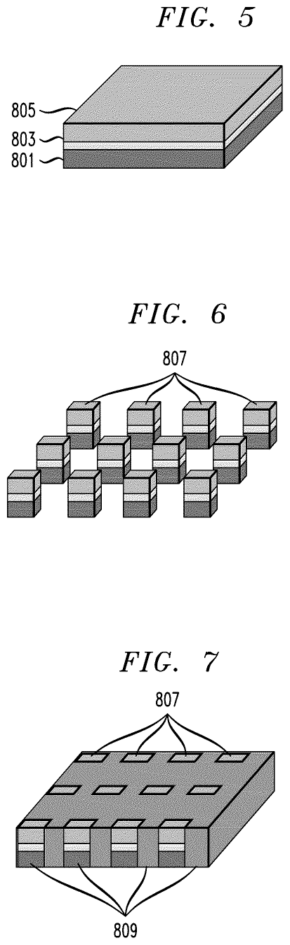

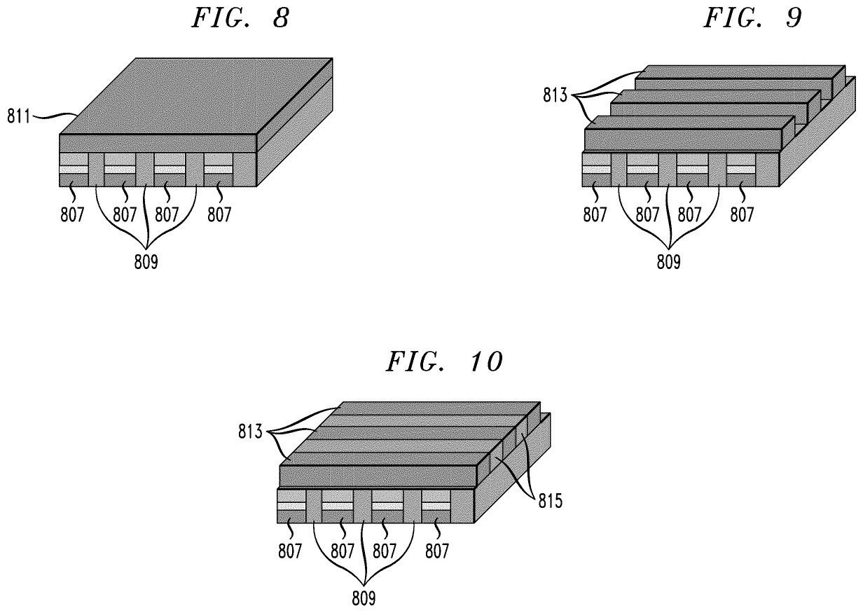

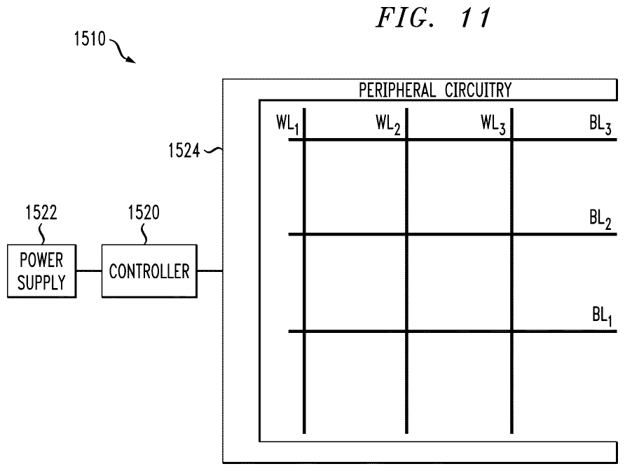

Referring now to FIGS. 4-10, consider an exemplary process flow. In FIG. 4, begin with a substrate 800 and form a metal hydride layer 801; for example, by depositing metal hydride MHₓ or depositing a blanket of metal and carrying out a hydrogen reaction (e.g., plasma/H₂ gas treatment). In a non-limiting example, the substrate can be silicon with pre-built access transistor devices and interconnects, capped in low-k dielectrics, such as SiCHO. The substrate is omitted from subsequent FIGS. 5-10 to avoid clutter. One non-limiting example of a suitable metal is Pd. One or more embodiments thus provide a method including imbuing ions into the metal electrode with plasma or a gas reaction. An ultrathin ion barrier layer 803 is formed on the metal hydride electrode, followed by an MIEC layer. This, in FIG. 5, form the aforementioned MIEC switching layer (preferably WO_{3-y})(generally, protonic switching memristive electrically resistive mixed ionic electronic conducting (MIEC) material) 805. In FIG. 6, etch the structure of FIG. 5 and form pillars 807. In FIG. 7, fill between the pillars with dielectric 809 and carry out chemical-mechanical planarization (CMP). In FIG. 8, deposit top contact metal 811 (e.g., Pd or alternative metal). In FIG. 9, etch the metal 811 to form bit lines 813. In FIG. 10, fill between the bit lines with another dielectric 815 and carry out chemical-mechanical planarization (CMP). Dielectric 815 can be the same or different as dielectric 809—suitable materials include, for example, Low-k dielectrics, such as SiCOH, SiCNO, and the like.

One or more embodiments provide a combined ion reservoir and electrode.

Some instances provide a configuration with an effective critical dimension (width) equivalency between the top electrode and the bottom electrode. The skilled artisan will appreciate that the equivalent CD of electrodes in MIEC devices is quite pertinent for reversible operation. If one electrode is confined, the field is much greater—this can be significant when trying to balance bipolar write operations.

The diffusion control layer in one or more embodiments is a chemical barrier; ions will move into it and across with intercalation. The ion barrier layer is kept atomically thin to prevent ion loss into the barrier and has a high electrical conductivity; namely, it is a potential barrier for ions (H+) only, but not for electrons.

Some instances provide non-filamentary operation of ion transfer. Indeed, one or more embodiments do not need and do not include an additional filamentary active layer to change resistance, which has asymmetric switching. Some instances are analog and symmetric switching.

One or more embodiments use ion movement for read/write of an analog memory, and do not use domain wall motion. Some instances include a diffusion control barrier in a two-terminal device that provides a non-destructive read, as opposed to prior-art ferroelectric tunnel junction (FTJ) devices which typically change state when subject to read voltages.

One or more embodiments use MIEC as a two-terminal memory device rather than as a selector for a memory. One or more embodiments provide analog devices for AI applications.

By having a diffusion barrier providing diffusion control, one or more embodiments provide appreciable endurance of the state and are non-volatile. In the prior art, as ions are moved, once the field is withdrawn, they will relax and move away from the interface due to chemical potential gradients.

Prior-art three-terminal devices require complicated integration to work on a large scale. One or more embodiments provide a two-terminal device for enhanced integration and scalability.

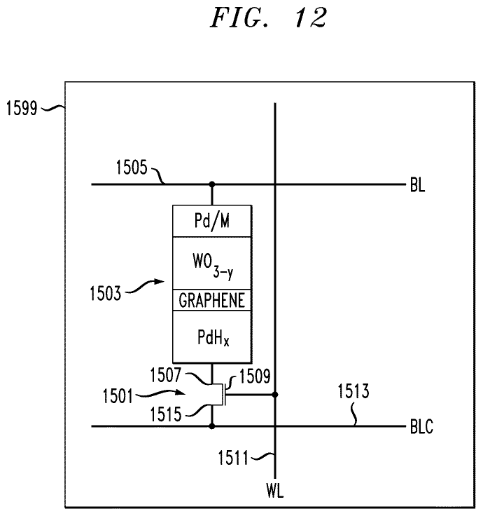

As noted, in one or more embodiments, cells in accordance with aspects of the invention are arranged into memory arrays; e.g., two- or three-dimensional cross-point arrays. As shown in FIG. 11, according to an exemplary embodiment, an array 1510 has peripheral circuitry 1524 coupled to a plurality of bit line pairs BL₁, BL₂, BL₃; a plurality of word lines WL₁, WL₂, WL₃; a power supply 1522, and a controller 1520 coupled to the power supply 1522 and the peripheral circuitry 1524. Three bit line pairs and three word lines are shown, but any desired number of bit line pairs and word lines can be provided. Only a single line is used to represent each bit line pair; however, details of the bit line pairs are shown in FIG. 12. Furthermore, a two-dimensional arrangement is shown in FIG. 11, but three-dimensional stacking is possible. At the intersection between the bit line pairs and word lines are a plurality of cell locations, each with a cell in accordance with aspects of the invention.

The power supply 1522 can be controlled by the controller 1520 to supply appropriate voltages for reading and writing, as described elsewhere herein, and can be part of the controller 1520 or a separate unit. Given the teachings herein, the skilled artisan will be able to provide any additional desired/required peripheral circuitry, voltage/power supply, elements to interface with peripheral circuitry, and the controller by adapting known techniques.

To implement any of the digital circuitry described herein, computer-aided semiconductor integrated circuit (IC) logic design, simulation, test, layout, and/or manufacture can be employed. The computerized design process can represent functional and/or structural design features in a design structure generated using electronic computer-aided design (ECAD). A suitable hardware-description language (HDL) can be employed. The skilled artisan can synthesize digital logic circuits to carry out desired control and other functionality, using known computer-aided design techniques. The controller 1520 carries out functions as defined herein; given the teachings and description of the functions herein, known control circuit technologies can be employed; e.g., multicycle or pipelined, hardwired or microprogrammed, using any suitable technology family (e.g., 7 nm CMOS, 5 NM CMOS, and the like). For example, the specified functions can be instantiated in logic circuitry using a known design flow process used for example, in semiconductor IC logic design, simulation, test, layout, and manufacture. Such a known design flow for synthesizing digital circuitry includes processes, machines and/or mechanisms for processing design structures or devices to generate logically or otherwise functionally equivalent representations of design structures and/or devices. The design structures processed can be encoded on machine-readable storage media to include data and/or instructions that when executed or otherwise processed on a data processing system generate a logically, structurally, mechanically, or otherwise functionally equivalent representation of hardware components, circuits, devices, or systems.

Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array). Design structures can be generated using ECAD. Use can be made of HDL design entities or other data structures conforming to and/or compatible with lower-level HDL design languages such as Verilog and VHDL, and/or higher level design languages such as C or C++. It is notable that FIG. 11 depicts a high-level schematic of the peripheral circuitry 1524, power supply 1522, and controller 1520. However, given the teachings herein, the skilled artisan can make appropriate connections to the bit line pairs and word lines and can add any additional elements as may be needed depending on the particular application at hand.

As shown in FIG. 12, each cell 1599 includes an access transistor device 1501 and an MIEC memory device 1503 (e.g., as shown in FIGS. 1-3). As seen in FIGS. 1-3, the memory device 1503 includes a metal-hydride bottom electrode 301; a ion barrier layer 303 with high electrical conductivity, high ion conductivity, and a higher ion chemical potential relative to the metal hydride; a mixed-ionic-electronic-conduction (MIEC) switching layer 305, outward of the barrier layer and having an electrical conductivity dependent on the ion concentration within the MIEC layer; and a top electrode 307 outward of the mixed-ionic-electronic-conduction (MIEC) switching layer. The top electrode 307 of the memory device is connected to a corresponding bit line 1505. The bottom electrode 301 of the memory device is connected to the drain 1507 of the access transistor device 1501. The gate 1509 of the access transistor device is connected a corresponding word line 1511. Each bit line pair includes a bit line (“BL”) 1505 and a complementary bit line (“BLC”) 1513. The source 1515 of the access transistor device is connected to the complementary bit line 1513.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with conventional techniques that can be adapted to form the starting structure, and with conventional techniques, such as lithography and etching, which can be adapted to carry out the patterning. The skilled artisan will be familiar with suitable materials for insulators (e.g., SiO₂), further metallization (e.g., copper with liners/barriers such as Ta, TaN), and the like.

Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary memory device includes a bottom electrically conductive layer 301, with a mobile ionizable species, and having an electrical resistance that is less than 5 percent of the overall resistance of the memory device. In one or more embodiments, the bottom electrically conductive layer is alloyed or intercalated with the mobile ionizable species. A barrier layer 303 is outward of the bottom electrically conductive layer and has a higher ion chemical potential relative to the bottom electrically conductive layer. A mixed-ionic-electronic-conduction (MIEC) switching layer 305 is outward of the barrier layer and has an electrical conductivity dependent on ion concentration within the MIEC layer. A top contact 307 is outward of the mixed-ionic-electronic-conduction (MIEC) switching layer.

In one or more embodiments, the total device resistance will be in the range from kΩ to MΩ due to the WOₓ layer, while the metal (Pd) will be on the order of Ω level resistance. The negligible value for PdHₓ means that in one or more embodiments it should be <10% of the device, or even less than 5% of the device, and will typically be <1%.

In some instances, the ions (i.e., of the mobile ionizable species) comprise hydrogen ions.

In one or more embodiments, the bottom electrically conductive layer comprises palladium.

In some cases, the barrier layer comprises graphene.

In some instances, the top contact includes palladium.

In one or more embodiments, the mixed-ionic-electronic-conduction (MIEC) switching layer comprises tungsten oxide.

One or more cases are directed to two-terminal memory devices; i.e., the bottom electrically conductive layer is a first terminal, the top contact is a second terminal, and the memory device does not include any terminals other than the first and second terminals.

In accordance with further aspects of the invention, an exemplary memory array (see, e.g., FIGS. 11 and 12) includes a plurality of word lines 1511 and a plurality of bit lines 1505 intersecting the plurality of word lines at a plurality of cell locations. Each bit line is paired with a corresponding complementary bit line 1513. In one or more embodiments, the complementary bit line is not physically located at the intersection of the bit line and the word line.

A plurality of cells are respectively located at the plurality of cell locations. Each cell of the plurality of cells in turn includes a memory device, and the memory device in turn includes: a bottom electrically conductive layer 301, with a mobile ionizable species, and having an electrical resistance that is less than 5 percent of the overall resistance of the memory device; a barrier layer 303, outward of the bottom electrically conductive layer and having a higher ion chemical potential relative to the bottom electrically conductive layer; a mixed-ionic-electronic-conduction (MIEC) switching layer 305, outward of the barrier layer and having an electrical conductivity dependent on ion concentration within the MIEC layer; and a top contact 307 outward of the mixed-ionic-electronic-conduction (MIEC) switching layer, and connected to a corresponding bit line. Each cell further includes an access transistor 1501 having a gate 1509 connected to a corresponding one of the plurality of word lines, a drain 1507 connected to the bottom electrically conductive layer, and a source 1515 connected to the corresponding complementary bit line.

In one or more embodiments, the bottom electrically conductive layer is alloyed or intercalated with the mobile ionizable species.

As noted above with regard to the memory device per se, in some instances, the ions (i.e., of the mobile ionizable species) comprise hydrogen ions. In one or more embodiments, the bottom electrically conductive layer comprises palladium. In some cases, the barrier layer comprises graphene. In some instances, the top contact includes palladium. In one or more embodiments, the mixed-ionic-electronic-conduction (MIEC) switching layer comprises tungsten oxide. One or more cases are directed to two-terminal memory devices; i.e., the bottom electrically conductive layer is a first terminal, the top contact is a second terminal, and the memory device does not include any terminals other than the first and second terminals.

In one or more embodiments, the array further includes peripheral circuitry 1524 coupled to the plurality of word lines and the plurality of bit lines and the plurality of complementary bit lines; and a controller-power supply 1520, 1522 configured to supply appropriate voltages for reading and writing the cells.

In accordance with still further aspects of the invention, an exemplary method of manufacturing an array of memory devices includes forming a metal hydride layer 801 (e.g., on a substrate 800); forming a barrier layer 803 outward of the metal hydride layer; forming a mixed-ionic-electronic-conduction (MIEC) switching layer 805 outward of the barrier layer to form a first intermediate structure; and etching the first intermediate structure to form a plurality of devices (pillars 807 in FIG. 6). Further steps include filling first dielectric material 809 between the plurality of devices and planarizing to form a second intermediate structure; depositing a top contact metal layer 811 over the second intermediate structure; etching the top contact metal layer to form a plurality of bit lines 813; and filling second dielectric material 815 between the plurality of bit lines, and planarizing.

One or more embodiments further include providing a substrate 800 with pre-built access transistor devices and interconnects, where the metal hydride layer 801 is formed on the substrate. The skilled artisan is familiar with techniques for forming access transistors and interconnects on a substrate, and, given the teachings herein, can adapt known techniques to implement aspects of the invention.

In some cases, forming the metal hydride layer comprises depositing metal hydride.

It is worth noting as an aside that in alternative embodiments, the access device is not a transistor (e.g., an Ovonic Threshold Switch (OTS) selector can be employed instead).

In one or more embodiments, forming the metal hydride layer comprises depositing metal and carrying out a hydrogenation reaction on the metal.

In some cases, the metal of the metal hydride layer comprises palladium.

In some instances, in the step of etching the first intermediate structure to form the plurality of devices, the metal hydride layers of the devices are in contact with drains of the access transistor devices.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed two-terminal MIECRAM device and/or arrays of such devices.

An integrated circuit in accordance with aspects of the present inventions can be employed in essentially any application and/or electronic system where one or more aspects of the disclosed two-terminal MIECRAM device and/or arrays of such devices would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. §1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A memory device comprising:
a bottom electrically conductive layer, with a mobile ionizable species, and having an electrical resistance that is less than 5 percent of the overall resistance of the memory device;
a barrier layer, outward of the bottom electrically conductive layer and having a higher ion chemical potential relative to the bottom electrically conductive layer;
a mixed-ionic-electronic-conduction (MIEC) switching layer, outward of the barrier layer and having an electrical conductivity dependent on ion concentration within the MIEC layer; and
a top contact outward of the mixed-ionic-electronic-conduction (MIEC) switching layer.

2. The memory device of claim 1, wherein the bottom electrically conductive layer is alloyed or intercalated with the mobile ionizable species.

3. The memory device of claim 1, wherein the ions comprise hydrogen ions.

4. The memory device of claim 1, wherein the bottom electrically conductive layer comprises palladium.

5. The memory device of claim 1, wherein the barrier layer comprises graphene.

6. The memory device of claim 1, wherein the top contact comprises palladium.

7. The memory device of claim 1, wherein the mixed-ionic-electronic-conduction (MIEC) switching layer comprises tungsten oxide.

8. The memory device of claim 1, wherein the bottom electrically conductive layer comprises a first terminal, the top contact comprises a second terminal, and the memory device does not include any terminals other than the first and second terminals.

9. A memory array comprising:
a plurality of word lines;
a plurality of bit lines intersecting the plurality of word lines at a plurality of cell locations, each bit line being paired with a corresponding complementary bit line; and
a plurality of cells respectively located at the plurality of cell locations; wherein each cell of the plurality of cells in turn comprises:
a memory device, the memory device in turn comprising:
a bottom electrically conductive layer, with a mobile ionizable species, and having an electrical resistance that is less than 5 percent of the overall resistance of the memory device;
a barrier layer, outward of the bottom electrically conductive layer and having a higher ion chemical potential relative to the bottom electrically conductive layer;
a mixed-ionic-electronic-conduction (MIEC) switching layer, outward of the barrier layer and having an electrical conductivity dependent on ion concentration within the MIEC layer; and
a top contact outward of the mixed-ionic-electronic-conduction (MIEC) switching layer, connected to a corresponding bit line; and
an access transistor having a gate connected to a corresponding one of the plurality of word lines, a drain connected to the bottom electrically conductive layer, and a source connected to the corresponding complementary bit line.

10. The memory array of claim 9, wherein the bottom electrically conductive layer is alloyed or intercalated with the mobile ionizable species.

11. The memory array of claim 9, wherein the ions comprise hydrogen ions.

12. The memory array of claim 9, wherein the bottom electrically conductive layer comprises palladium.

13. The memory array of claim 9, wherein the barrier layer comprises graphene.

14. The memory array of claim 9, wherein the mixed-ionic-electronic-conduction (MIEC) switching layer comprises tungsten oxide.

15. The memory array of claim 9, wherein, for each memory device, the bottom electrically conductive layer comprises a first terminal, the top contact comprises a second terminal, and the memory device does not include any terminals other than the first and second terminals.

16. The memory array of claim 9, further comprising:
peripheral circuitry coupled to the plurality of word lines and the plurality of bit lines; and
a controller-power supply configured to supply appropriate voltages for reading and writing the cells.

17. A method of manufacturing an array of memory devices, comprising:
forming a metal hydride layer;
forming a barrier layer outward of the metal hydride layer;
forming a mixed-ionic-electronic-conduction (MIEC) switching layer outward of the barrier layer to form a first intermediate structure;
etching the first intermediate structure to form a plurality of devices;
filling first dielectric material between the plurality of devices and planarizing to form a second intermediate structure;
depositing a top contact metal layer over the second intermediate structure;
etching the top contact metal layer to form a plurality of bit lines; and
filling second dielectric material between the plurality of bit lines and planarizing.

18. The method of claim 17, further comprising providing a substrate with pre-built access transistor devices and interconnects, wherein the metal hydride layer is formed on the substrate.

19. The method of claim 17, wherein forming the metal hydride layer comprises depositing metal hydride.

20. The method of claim 17, wherein forming the metal hydride layer comprises depositing metal and carrying out a hydrogenation reaction on the metal.
